(19) United States
(12) Patent Application Publication
(10) Pub. No.: US 2024/0203801 A1
(43) Pub. Date: Jun. 20, 2024

(54) TEST PAD ON DEVICE LEAD FOR TEST CONTACTOR

(71) Applicant: Texas Instruments Incorporated, Dallas, TX (US)

(72) Inventors: John Carlo Molina, Limay (PH); Ray Fredric De Asis, Mabalacat City (PH); Julian Carlo Barbadillo, Mabalacat City (PH)

(21) Appl. No.: 18/069,224

(22) Filed: Dec. 20, 2022

(51) Int. Cl. H01L 21/66; G01R 31/28; H01L 23/00; H01L 23/495

(52) U.S. Cl. CPC H01L 22/32; G01R 31/2896; H01L 23/49503; H01L 23/49541; H01L 24/05; H01L 24/48; H01L 2224/05554; H01L 2224/48157

(57) ABSTRACT

An example semiconductor package comprises a semiconductor die having a top side with bond pads and a leadframe including a die attach pad. A bottom side of the semiconductor die is mounted on the die attach pad using a die attach material. The leadframe has at least one lead with a top surface and a bottom surface. At least one bond pad is coupled to the top surface of at least one lead by a bond wire. A mold compound covers the semiconductor die, the bond wires, and at least a portion of the at least one lead. A test pad is located on or adjacent to the bottom surface of the at least one lead. The test pad is electrically coupled to the at least one lead.

### BACKGROUND

Packaged electronic assemblies, such as packaged integrated circuits, generally include a leadframe including leads and pads for one or more semiconductor dies. A plastic or resin mold encapsulates the package and protects the semiconductor dies and the electrical connections between the dies and leads. In a transfer molding process to form the package, the mold compound, such as a plastic or resin compound, is injected to fill cavity molds containing the semiconductor die and leadframe assemblies. The mold compound cures around the semiconductor die and leadframe assemblies to form protective packages for the electronic assemblies. For package molding applications, mold compounds may be thermoset compounds that include an epoxy resin or similar material combined with a filler, such as alumina, and other materials to make the compound suitable for molding, such as accelerators, curing agents, filters, and mold release agents.

### SUMMARY

A semiconductor package comprises a semiconductor die having a top side with bond pads and a leadframe including a die attach pad. A bottom side of the semiconductor die is mounted on the die attach pad using a die attach material. The leadframe has at least one lead with a top surface and a bottom surface. Bond pads are coupled to the top surface of leads by bond wires. A mold compound covers the semiconductor die, the bond wires, and at least a portion of the leads. A test pad is located on or adjacent to the bottom surface of a lead. The test pad is electrically coupled to the lead.

In a first arrangement, the test pads are an integral part of the bottom surface of the leads. The test pads protrude away from the bottom surface of the leads.

In a second arrangement, the test pads extend from a side of the leads. The test pads are an integral part of the leads. The test pads protrude away from the bottom surface of the leads. The test pads are located adjacent to a corner of the leads. The leads have a notch out of a corner or side. The notch is configured to increase separation between the leads and test pads on adjacent leads. The test pad is attached to a first corner of the lead and the notch corresponds to a missing second corner of the lead. The first corner and the notch may be positioned along a same side of the lead.

In a third arrangement, the test pad is spaced apart from a side of the lead by a channel. The channel is filled with the mold compound. The test pad is electrically coupled to the lead under the mold compound. The test pad is located adjacent to a corner of the lead. The lead has a notch out of a corner or side. The notch is configured to increase separation between the lead and a test pad on an adjacent lead. The test pad is attached to a first corner of the lead and the notch corresponds to a missing second corner of the lead. The first corner and the notch may be positioned along a same side of the lead. The test pad may protrude away from the bottom surface of the lead.

An integrated circuit (IC) package comprises a leadframe including a die attach pad and a plurality of leads spaced apart from the die attach pad. Each lead has a top surface and a bottom surface. A semiconductor die has a top side with bond pads and a bottom side that is mounted on the die attach pad using a die attach material. The bond pads are individually coupled to the top surface of selected ones of the leads by bond wires. A mold compound covers the semiconductor die, the bond wires, and at least a portion of the plurality of leads. Each of the plurality of leads has a test pad located on or adjacent to the bottom surface of the lead. Each test pad is electrically coupled to a respective lead.

In a first arrangement of the IC package, each test pad is an integral part of the bottom surface of the respective lead. Each test pad protrudes away from the bottom surface of the respective lead.

In a second arrangement of the IC package, each test pad extends from a side of the respective lead. Each test pad is an integral part of the respective lead. Each test pad protrudes away from the bottom surface of the respective lead. The test pads are located adjacent to a corner of their respective leads. The plurality of leads each have a notch out of a corner or side. The notch is configured to increase separation between test pads and neighboring leads. Each test pad is attached to a first corner of the respective lead and the notch corresponds to a missing second corner of the lead. The first corner and the notch are positioned along a same side of the lead.

In a third arrangement of the IC package, each test pad is spaced apart from a side of the respective lead by a channel. The channel is filled with the mold compound. Each test pad electrically coupled to the respective lead under the mold compound. The test pads are located adjacent to a corner of their respective leads. Each lead has a notch out of a corner or side. The notch is configured to increase separation between the lead and neighboring test pad. Each test pad may be flush with the bottom surface of the respective lead or may protrude away from the bottom surface.

### BRIEF DESCRIPTION OF THE DRAWINGS

Having thus described the invention in general terms, reference will now be made to the accompanying drawings, wherein:

FIG. 1A illustrates a top view of a completed semiconductor package that has been singulated from a leadframe strip.

FIG. 1B illustrates a bottom view of the semiconductor package as shown in FIG. 1A

FIGS. 2A and 2B illustrate leads having test pads extending from a surface of the leads.

FIGS. 3A and 3B illustrates leads having test pads that are located along an outside edge of the original lead outline and extending above the surface of the leads.

FIGS. 4A and 4B illustrate leads having test pads that are positioned outside the original lead outline and separated from the leads by a partially etched region.

FIG. 5 illustrates a bottom view of a semiconductor package with test pads as shown in FIGS. 2A and 2B.

FIG. 6 illustrates a bottom view of an alternative semiconductor package with test pads as shown in FIGS. 4A and 4B.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Elements that are electrically connected with intervening wires or other conductors are considered to be coupled. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor die” is used herein. A semiconductor die can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, such as a microprocessor or memory device. The semiconductor device may also be referred to herein as a semiconductor device or an integrated circuit (IC) die.

The term “semiconductor package” is used herein. A semiconductor package has at least one semiconductor die electrically coupled to terminals and has a package body that protects and covers the semiconductor die. In some arrangements, multiple semiconductor dies can be packaged together. For example, a power metal oxide semiconductor (MOS) field effect transistor (FET) semiconductor device and a second semiconductor device (such as a gate driver die, or a controller die) can be packaged together to from a single packaged electronic device. Additional components such as passive components, such as capacitors, resistors, and inductors or coils, can be included in the packaged electronic device. The semiconductor die is mounted with a package substrate that provides conductive leads. A portion of the conductive leads form the terminals for the packaged device. In wire-bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. The semiconductor package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

The term “test pad” is used herein. A test pad is a contact surface on a device that is configured for use with test equipment, such as contactor pins that are adapted to electrically connect to the test pad. The test pads are electrically connected to leads on the device. The test equipment may exchange signals with the device via the contactor pins instead of using the device leads. Test pads differ from the device input and output contacts in that they are used to provide temporary test access to the device and not for functional communication to circuits external to the device. A test pad is a specific area where the contactor pins probe onto for testing a semiconductor device. The test pad area can be on a different height or at a different location relative to the actual lead, but the test pad is still electrically connected to the actual lead. The test pad can also represent an area that will be used for high volume testing in terms of pitch and contact.

Semiconductor devices are manufactured from semiconductor wafers by depositing materials, such as metal and dielectric layers, on the wafer and then selectively masking and etching the layers. Many integrated circuit (IC) devices may be fabricated on a single semiconductor wafer by processing arrays of semiconductor die locations across the wafer. Individual semiconductor dies, each having an individual integrated circuit, are then singulated from the wafer. These individual semiconductor dies may then be further processed, such as by mounting the semiconductor die on a leadframe to create a semiconductor package.

Leadframes are formed on a single sheet of metal by stamping or etching. Multiple interconnected leadframes may be formed from a single sheet of substrate, the interconnected leadframes are referred to as a leadframe strip. Tie bars interconnect leads, die mount pads, and other elements of a leadframe to one another as well as to elements of adjacent leadframes in a leadframe strip. A siderail may surround the array of leadframes to provide rigidity and support leadframe elements on the perimeter of the leadframe strip.

Die mounting typically takes place while the leadframes are still integrally connected as a leadframe strip. Semiconductor dies are attached to the leadframe die attach pads, wire bonding electrically connects the dies to lead contacts on the leadframe strip, and a molding compound is applied to cover at least part of the leadframe and semiconductor dies After the mounting process is completed, the leadframes and mold compound of individual devices are severed (“singulated” or “diced”) with a cutting tool, such as a saw or laser. These singulation cuts separate the leadframe strip into separate semiconductor packages, each semiconductor package including a singulated leadframe, at least one semiconductor die, electrical connections between the die and leadframe (such as gold or copper bond wires), and the mold compound that covers at least part of these structures.

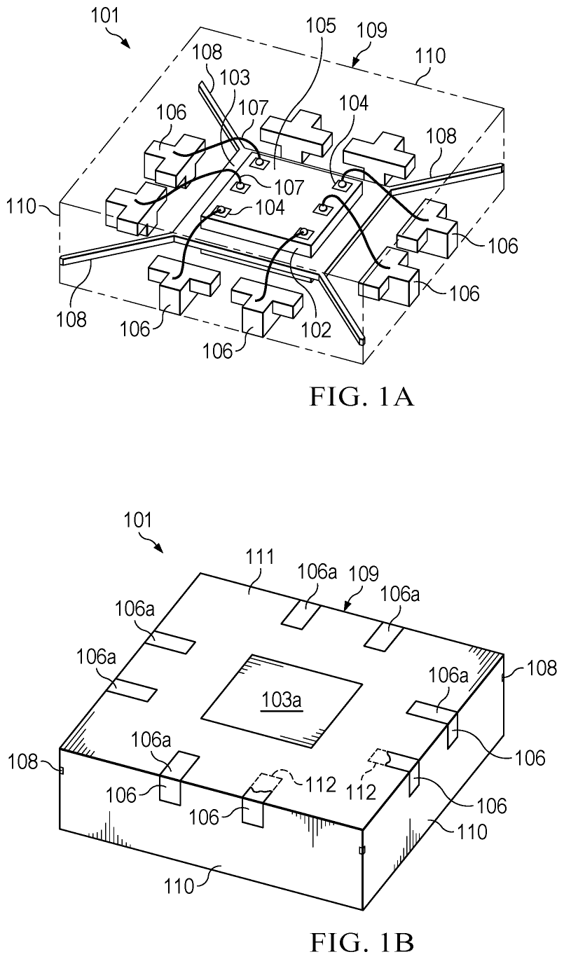

FIG. 1A illustrates a top view of a completed semiconductor package 101 that has been singulated from a leadframe strip. A semiconductor die 102 is mounted on a die attach pad portion 103 of the leadframe strip using a die attach film or paste. Bond pads 104 on the top surface 105 of semiconductor die 102 are connected to lead contacts 106 by bond wires 107. Tie bars 108 couple the die attach pad 103 to other leadframe components. Tie bars 108 are cut during singulation to electrically isolate die attach pad 103. After wire bonding, the semiconductor die 102 and lead contacts 106 are encapsulated in a mold compound 109 (shown as a dashed line), such as a plastic material, to form the semiconductor package 101. The mold compound 109 generally leaves only the outer leadframe portions exposed, such as the sides and undersides of the die attach pad 103 and lead contacts 106. The tie bars 108 are encapsulated in the mold compound 109 may extend to, and be exposed at, the sides 110 of semiconductor package 101.

FIG. 1B illustrates a bottom view of the semiconductor package 101 as shown in FIG. 1A. Lead contacts 106 and tie bars 108 are exposed through the mold compound 109 on the sides 110 of semiconductor package 101. On the bottom surface 111 of semiconductor package 101, a bottom surface 106a of lead contacts 106 and a bottom surface 103a of die attach pad 103 are exposed. During a molding process to create the semiconductor package 101, excess pressure in a mold cavity may result in undesirable mold flash 112 that flows under the leadframe and covers the bottom surface 106a of some lead contacts 106. As a result, the bottom surface 106a of some contacts 106 may be partially or completely covered by mold flash 112. Depending upon the amount and location of the mold flash 112, external contactors may not be able to make an electrical connection to lead contact 106 during operation or test of semiconductor package 101.

Due to inadequacies in the packaging process or defects in the semiconductor wafer, certain ones of the semiconductor package 101 or integrated circuits 102 will not function as designed. Such defects may be detected initially or may not become apparent until an integrated circuit has been in operation for a period of time. Therefore, it is desirable to test and electrically stress the semiconductor package 101 to determine which circuits are operational and which ones are defective or likely to become defective. Semiconductor packages are typically subjected to a series of test procedures during the manufacturing process in order to verify functionality and reliability. A test approach may include using a contactor card for contact testing of semiconductor package 101. Contactor pins (not shown) align with and touch the surface 106a of corresponding contact leads 106 on a semiconductor package to test electrical connections within, and/or operation of, semiconductor package 101. The contactors electrically connect the individual leads 106 of semiconductor package 101 to a test apparatus.

Mold flash 112 may prevent contact pins from making electrical contact with leads 106, which would prevent adequate testing of the semiconductor package 101 and would result in an erroneous indication that the device failed testing. During development of semiconductor devices, the test contactors need to be designed early in the device development to support a test solution. However, developers are unlikely to collect enough good samples from devices with complex leadframe designs and process flows when there is mold flash on the leads. While the manufacturing process is being refined, mold flash or resin bleed is likely to cover areas needed for contact testing. One solution to the mold flash problem during device development is to include a test pad feature on the leads. In one arrangement, the test pad may be located at the center of the contact leads with sufficient area to cover the tolerance of contactor movement during testing. The test pad feature is higher than the rest of the contact lead to prevent mold flashes from migrating over the top of the test pad. In another arrangement, the test pad may be located outside the original lead outline either with a full metal connection protruding from lead surface or with a half-etch feature around the test pad making it look like an island near the lead.

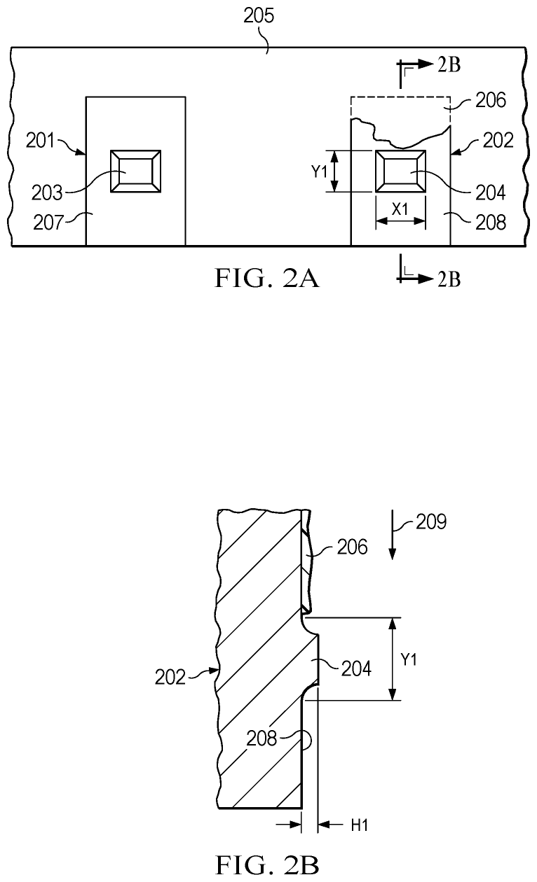

FIG. 2A illustrates leads 201, 202 having test pads 203, 204, respectively. Mold compound 205 surrounds leads 201, 202. In one arrangement, the view illustrated in FIG. 2A shows a portion of the bottom surface of a semiconductor package. Mold flash 206 has bled over the surface 208 of lead 202 during the molding process. Mold flash 206 may be caused, for example, by excess pressure during the molding process or by a warped leadframe that exposed surface 208. Test pads 203, 204 are located on surfaces 207, 208 of leads 201, 202 and extend away from the surfaces 207, 208.

FIG. 2B is a cross section of lead 202 in FIG. 2A. FIG. 2B illustrates the test pad 204 on lead 202 extending a height H1 away from surface 208 on lead 202. Height H1 may be 15-20 um in one arrangement, which would be sufficient to avoid 10-15 um of mold flash. The height H1 may be selected in other arrangements based upon expected mold flash risks. As shown in FIG. 2B, mold compound flows in the direction of flashing 209. As the mold compound 205 overruns lead 202 and creates mold flash 206, test pad 204 acts as an island so that the mold compound 205 does not migrate over the surface of test pad 204. This leaves a contact surface at least at test pad 204 that can be electrically connected to test contactors.

Observations of semiconductor packages that are defective due to mold flash indicate that a mold flash thickness of 10-15 um is typical. In such devices, the mold flash partially covers leads. Devices with a thicker amount of mold flash (i.e., greater than about 15 um) result in entire leads being overrun by mold compound and thereby rendered unusable. This larger amount of mold flash indicates a bigger problem with the molding process that is not relevant to the electrical testing of development units.

Test pads 203, 204 are located at the center of leads 201, 202 in the illustrated configuration. In other arrangements, test pads 203, 204 may be positioned closer to one of the edges of leads 201, 202 when, for example, such a position might minimize mold flash on the test pads 203, 204. Test pads 203, 204 have a width X1 and a length Y1. These dimensions are selected to provide a sufficient area to cover the tolerance of contactor movement during test procedures.

Test pads 203, 204 may be formed during a leadframe manufacturing process by partially etching material surrounding test pads 203, 204 on the surface of leads 201, 202 thereby leaving behind the raised test area. In other arrangements, during the leadframe manufacturing process, metal is deposited on the leadframe at leads 201, 202 to create the raised test area.

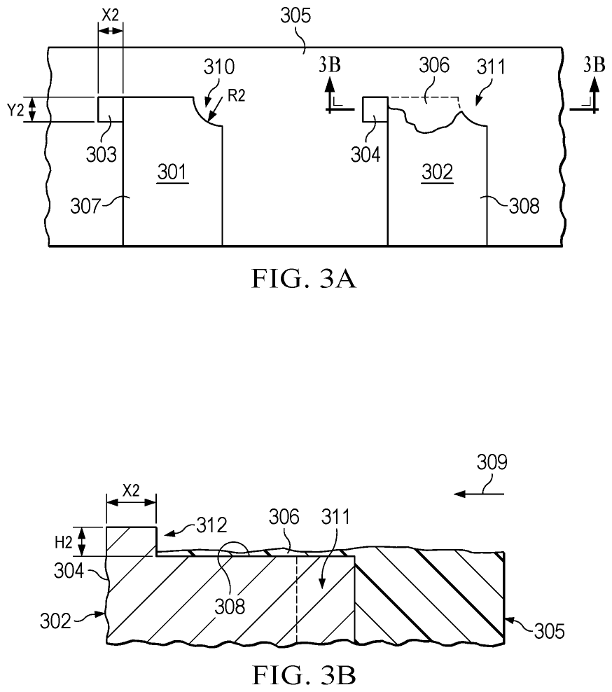

FIG. 3A illustrates an arrangement in which leads 301, 302 have test pads 303, 304, respectively, that are located outside the original lead outline. Mold compound 305 surrounds leads 301, 302 and test pads 303, 304. Test pads 303, 304 protrude above the surfaces 307, 308 of leads 301, 302. Mold flash 306 has bled over the surface 308 of lead 302 during the molding process but does not migrate over test pad 304 due to the excess height H2. In the illustrated example, the mold flash is flowing in direction 309 and does not reach the surface 307 of lead 301.

FIG. 3B is a cross section of lead 302 in FIG. 3A. FIG. 3B shows that test pad 304 is a full metal region attached physically and electrically to lead 302. Test pad 304 protrudes above the surface 308 of lead 302 by a height H2. For example, surface 308 may define a plane across the bottom surface of a semiconductor package, and test pad 304 extends through and away from that plane. Height H2 may be 15-20 um in one arrangement, which would be sufficient to avoid 10-15 um of mold flash. The height H2 may be selected in other arrangements based upon expected mold flash risks. As the mold compound 305 migrated in direction 309 and overruns lead 302, mold flash 306 covers at least a portion of surface 308. The test pad 304 acts as an island so that the mold compound 305 does not migrate over the top surface of test pad 304. This leaves a contact surface at least at test pad 304 that can be electrically connected to test contactors.

Test pads 303, 304 are located at a corner of leads 301, 302 in the illustrated configuration. In other arrangements, test pads 303, 304 may be positioned anywhere along the edges of leads 301, 302 when, for example, such a position might minimize mold flash on the test pads 303, 304. Test pads 303, 304 have a width X2 and a length Y2. These dimensions are selected to provide a sufficient area to cover the tolerance of contactor movement during test procedures.

A notch 310 is created on a corner of lead 301 adjacent to the location of the test pad 304 on lead 302. The notch 310 ensures that test pad 304 is not too close to lead 301 and prevents electrical coupling between leads 301, 302. Lead 302 had a similar notch 311 to ensure spacing from a test pad (not shown) on the other side. Notch 310 is shown as a circular shape having radius R2. In other arrangements, notch 310 may have any appropriate shape with a curved or linear outline that provides the desired spacing between lead 301 and test pad 304.

Test pads 303, 304 may be formed during a leadframe manufacturing process by partially etching material on the surface of leads 301, 302 thereby leaving behind the raised test area 303, 304. In other arrangements, during the leadframe manufacturing process, metal is deposited on the leadframe in the area of test pads 303, 304 of to create raised portions 312.

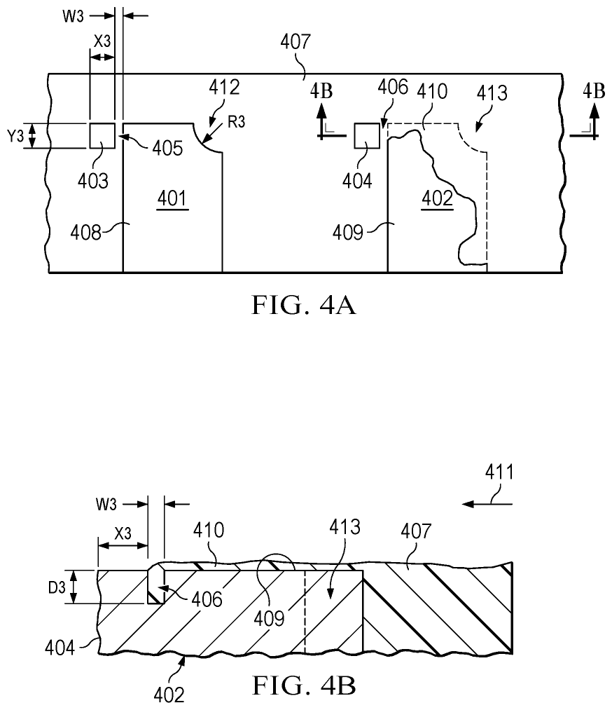

FIG. 4A illustrates an arrangement in which leads 401, 402 have test pads 403, 404, respectively, that are positioned outside the original lead outline. Test pads 403, 404 are separated from their respective leads 401, 402 by a partially etched region 405, 406. The etched region 405, 406 may be half etched so that the test pads 403, 404 look like an island separated from their leads 401, 402. Mold compound 407 surrounds leads 401, 402 and test pads 403, 404. In the illustrated arrangement, the tops of test pads 403, 404 are flush with surfaces 408, 409 of leads 401, 402. In other arrangements, test pads 403, 404 may protrude above the surface of leads 401, 402 as illustrated in FIGS. 3A and 3B.

Mold flash 410 has bled over the surface 409 of lead 402 during the molding process but does not migrate over test pad 404. The etched regions 405, 406 capture excess mold compound and direct it away from test pads 403, 404. In the illustrated example, the mold flash 410 is flowing in direction 411 and does not reach the surface 408 of lead 401.

FIG. 4B is a cross section of lead 402 shown in FIG. 4A. FIG. 4B shows that test pad 404 is a full metal region that is attached physically and electrically to lead 402. The etched region 406 between test pad 404 and lead 402 has a depth D3. Depth D3 may be approximately half the thickness of the leadframe. For an 8 mil leadframe, depth D3 may be about 4 mils. The depth D3 may be selected in other arrangements based upon expected mold flash risks. As the mold compound 407 migrated in direction 411 and overruns lead 402, mold flash 410 covers at least a portion of surface 409. The etched region 406 acts as a channel or trench to direct the mold compound 407 around the test pad 404 so that test pad 404 is not covered by mold flash 410. This leaves a contact surface at least at test pad 404 that can be electrically connected to test contactors. The channel 406 has a width W3 and a depth D3. The dimensions of width W3 and a depth D3 may be selected based upon expected mold flash risks for a particular design of a semiconductor package, molding process, and/or mold compound.

Test pads 403, 404 are located generally at a corner of leads 401, 402 in the illustrated configuration. In other arrangements, test pads 403, 404 may be positioned anywhere along the edges of leads 401, 402 when, for example, such a position might minimize mold flash on the test pads 403, 404. Test pads 403, 404 have a width X3 and a length Y3. These dimensions are selected to provide a sufficient area to cover the tolerance of contactor pin movement during test procedures.

A notch 412 is created on a corner of lead 401 adjacent to the location of the test pad 404 for lead 402. The notch 412 ensures that test pad 404 is not too close to lead 401 and prevents electrical coupling between leads 401, 402. Lead 402 had a similar notch 413 to ensure spacing from a test pad (not shown) on the other side. Notch 412 is shown as a circular shape having radius R2. In other arrangements, notch 412 may have any appropriate shape with a curved or linear outline that provides the desired spacing between lead 401 and test pad 404.

Test pads 403, 404 may be formed during a leadframe manufacturing process by partially etching material on the leadframe surface near leads 401, 402 thereby leaving behind the isolated test areas 403, 404. In other arrangements, during the leadframe manufacturing process, metal is deposited on the test area 403, 404 sections of the leadframe to create a raised portion at test pad locations 403, 404.

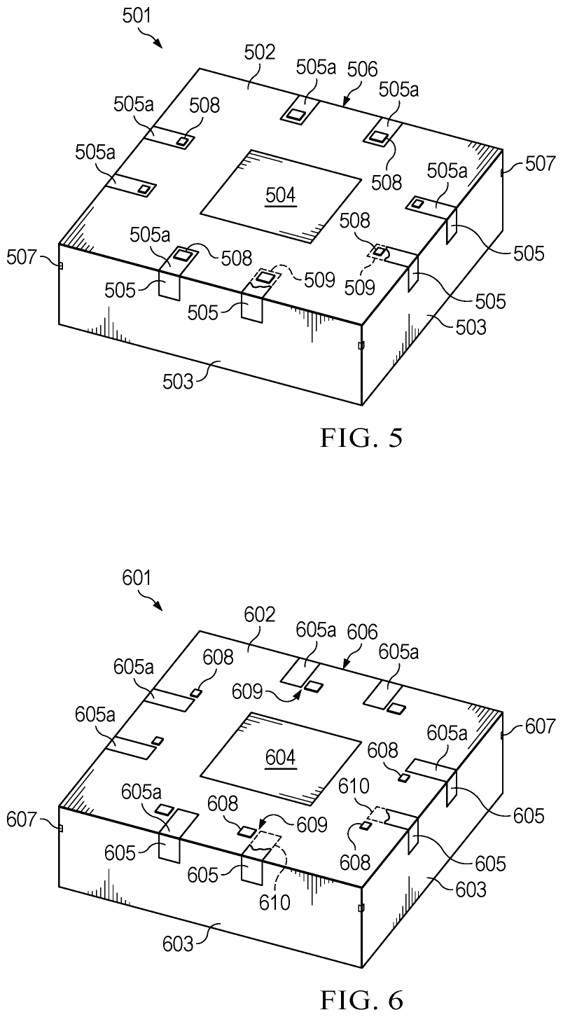

FIG. 5 illustrates a bottom view of a semiconductor package 501 having a bottom surface 502 and sides 503. On the package bottom surface 502, a die attach pad bottom surface 504 is exposed. A number of leads 505 are exposed on the sides 503 of semiconductor package 501 through mold compound 506. Cross tie bars 507 that were cut during singulation of the package 501 are also exposed. The leads 505 have a bottom surface 505a. A test pad 508 is formed on the bottom surface 505a of each lead 505. The test pads extend above or protrude from bottom surface 505a as illustrated in FIGS. 2A and 2B for test pads 203, 204.

During production in a molding process, mold flash 509 may cover the bottom surface 505a on some leads 505. This mold flash 509 may prevent test contactors from touching the bottom surface 505a of the affected leads 505. However, because test pads 508 extend above the bottom surface 505a, the mold flash 509 does not cover the test pads 508. Test contactor pins (not shown) are aligned with the test pads 508 so that when moved against semiconductor package 501, the test contactor pins make electrical contact with all of leads 505 without interference from mold flash 509.

In other arrangements, the test pads on the bottom 502 of semiconductor package 501 at leads 505 may be formed as shown in FIGS. 3A and 3B or FIGS. 4A and 4B. The size and the position of the test pads may be selected based upon the expected mold flash risks of a certain package design or manufacturing process.

FIG. 6 illustrates a bottom view of an alternative semiconductor package 601 having a bottom surface 602 and sides 603. On the package bottom surface 602, a die attach pad bottom surface 604 is exposed. A number of leads 605 are exposed on the sides 603 of semiconductor package 601 through mold compound 606. Cross tie bars 607 that were cut during singulation of the package 601 are also exposed. The leads 605 have a bottom surface 605a. A test pad 608 is formed adjacent to a corner of each lead 605 but outside the outline of the lead 605. The test pads 608 are separated from the bottom surface 605a of a nearby lead 605 by an etched channel 609 as illustrated in FIGS. 4A and 4B as channel 405, 406 for test pads 403, 404.

The test pads 608 may be flush with the bottom surface 605a of leads 605. Alternatively, the test pads may be built up to extend above the bottom surface 605a of each lead 605 by a predetermined height.

During production in a molding process, mold flash 610 may cover the bottom surface 605a on some leads 605. This mold flash 610 may prevent test contactors from touching the bottom surface 605a of the affected leads 605. However, because test pads 608 have a channel 609 separating them from the bottom surface 605a, the mold flash 609 does not cover the test pads 608. Instead, any excess mold compound flows into channel 609 and around test pads 608. Test contactor pins (not shown) are aligned with the test pads 608 so that when moved against semiconductor package 601, the test contactor pins make electrical contact with all of leads 605 without interference from mold flash 610.

In other arrangements, the test pads on the bottom 602 of semiconductor package 601 at leads 605 may be formed as shown in FIGS. 3A and 3B. The size and the position of the test pads may be selected based upon the expected mold flash risks of a certain package design or manufacturing process.

An example semiconductor package comprises a semiconductor die having a top side with bond pads and a leadframe having a die attach pad. A bottom side of the semiconductor die is mounted on the die attach pad using a die attach material. The leadframe has at least one lead with a top surface and a bottom surface. Bond pads are coupled to the top surface of the leads by a bond wire. A mold compound covers the semiconductor die, the bond wires, and at least a portion of the leads. A test pad is spaced apart from a side of each lead by a channel. The channel is filled with the mold compound. The test pads are electrically coupled to the leads under the channel. The test pads protrude out of a plane defined by the bottom surface of the lead. The test pad may have a height of 10-15 um away from the bottom surface.

A test pad may be located adjacent to a corner of a lead. The lead may have a notch out of another corner or a side. The notch is configured to increase separation between the lead and a test pad on an adjacent lead. The test pad may be attached to a first corner of the lead and the notch may correspond to a missing second corner of the lead. The first corner and the notch are positioned along a same side of the lead.

Another example semiconductor package comprises a semiconductor die having a top side with bond pads and a leadframe including a die attach pad. A bottom side of the semiconductor die is mounted on the die attach pad using a die attach material. The leadframe has a plurality of leads, each with a top surface and a bottom surface. The bond pads are individually coupled to the top surface of leads by bond wires. A mold compound covers the semiconductor die, the bond wires, and at least a portion of the leads. A test pad is located on or adjacent to the bottom surface of one or more leads. The test pads are electrically coupled to a lead.

The test pad may be an integral part of the bottom surface of the lead. The test pad may protrude away from the bottom surface of the at least one lead by a height or distance. The test pad has a height of 10-15 um in some examples.

The test pad may extend from a side of the lead, where the test pad is an integral part of the lead. The test pad may also protrude away from the bottom surface of the at least one lead. The test pad may be located adjacent to a corner of the lead. The lead may have a notch out of a corner or side. The notch is configured to increase separation between the lead and a test pad on an adjacent lead.

In another example, an integrated circuit (IC) package comprises a leadframe including a die attach pad and a plurality of leads spaced apart from the die attach pad. Each lead has a top surface and a bottom surface. A semiconductor die has a top side with bond pads and a bottom side mounted on the die attach pad using a die attach material. The bond pads are individually coupled to the top surface of selected ones of the leads by bond wires. A mold compound covers the semiconductor die, the bond wires, and at least a portion of the plurality of leads. Each of the plurality of leads has a test pad located on or adjacent to the bottom surface of the lead, wherein each test pad is electrically coupled to a respective lead.

In the IC package, each test pad may be an integral part of the bottom surface of the respective lead. Each test pad protrudes or extends away from the bottom surface of the respective lead.

In the IC package, each test pad may extend from a side of the respective lead. Each test pad is an integral part of the respective lead, and each test pad extends or protrudes away from the bottom surface of the respective lead.

In the IC package, each test pad may be located adjacent to a corner of the respective lead. The plurality of leads each have a notch out of a corner or side. The notch is configured to increase separation between test pads and neighboring leads. Each test pad is attached to a first corner of the respective lead and the notch corresponds to a missing second corner of the lead. The first corner and the notch positioned along a same side of the lead.

In the IC package, each test pad may be spaced apart from a side of the respective lead by a channel. The channel is filled with the mold compound, and each test pad electrically coupled to the respective lead under the mold compound.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A semiconductor package, comprising:
a semiconductor die having a top side with bond pads;
a leadframe including a die attach pad, a bottom side of the semiconductor die mounted on the die attach pad using a die attach material, the leadframe having at least one lead with a top surface and a bottom surface, wherein at least one bond pad is coupled to the top surface of at least one lead by a bond wire;
a mold compound covering the semiconductor die, the bond wires, and at least a portion of the at least one lead; and
a test pad spaced apart from a side of the at least one lead by a channel, the channel filled with the mold compound, the test pad electrically coupled to the at least one lead under the channel, and the test pad protruding out of a plane defined by the bottom surface of the at least one lead.

2. The semiconductor package of claim 1, wherein the test pad has a height of 10-15 um away from the bottom surface.

3. The semiconductor package of claim 1, wherein the test pad is located adjacent to a corner of the at least one lead.

4. The semiconductor package of claim 3, wherein the at least one lead has a notch out of a corner or side, the notch configured to increase separation between the at least one lead and a test pad on an adjacent lead.

5. The semiconductor package of claim 4, wherein the test pad is attached to a first corner of the at least one lead and the notch corresponds to a missing second corner of the at least one lead, the first corner and the notch positioned along a same side of the at least one lead.

6. A semiconductor package, comprising:
a semiconductor die having a top side with bond pads;
a leadframe including a die attach pad, a bottom side of the semiconductor die mounted on the die attach pad using a die attach material, the leadframe having at least one lead with a top surface and a bottom surface, wherein at least one bond pad is coupled to the top surface of at least one lead by a bond wire;
a mold compound covering the semiconductor die, the bond wires, and at least a portion of the at least one lead; and
a test pad located on or adjacent to the bottom surface of the at least one lead, the test pad electrically coupled to the at least one lead.

7. The semiconductor package of claim 6, wherein the test pad is an integral part of the bottom surface of the at least one lead, the test pad protruding away from the bottom surface of the at least one lead.

8. The semiconductor package of claim 7, wherein the test pad has a height of 10-15 um.

9. The semiconductor package of claim 6, wherein the test pad extends from a side of the at least one lead, the test pad is an integral part of the at least one lead, and the test pad protrudes away from the bottom surface of the at least one lead.

10. The semiconductor package of claim 9, wherein the test pad is located adjacent to a corner of the at least one lead.

11. The semiconductor package of claim 10, wherein the at least one lead has a notch out of a corner or side, the notch configured to increase separation between the at least one lead and a test pad on an adjacent lead.

12. The semiconductor package of claim 11, wherein test pad is attached to a first corner of the at least one lead and the notch corresponds to a missing second corner of the at least one lead, the first corner and the notch positioned along a same side of the at least one lead.

13. The semiconductor package of claim 9, wherein the test pad protrudes away from the bottom surface of the at least one lead.

14. The semiconductor package of claim 13, wherein the test pad has a height of 10-15 um relative to the bottom surface of the at least one lead.

15. An integrated circuit (IC) package, comprising:
a leadframe including a die attach pad and a plurality of leads spaced apart from the die attach pad, each lead having a top surface and a bottom surface;
a semiconductor die having a top side with bond pads and a bottom side mounted on the die attach pad using a die attach material, wherein the bond pads are individually coupled to the top surface of selected ones of the leads by bond wires;
a mold compound covering the semiconductor die, the bond wires, and at least a portion of the plurality of leads; and
each of the plurality of leads having a test pad located on or adjacent to the bottom surface of the lead, each test pad electrically coupled to a respective lead.

16. The IC package of claim 15, wherein each test pad is an integral part of the bottom surface of the respective lead, each test pad protruding away from the bottom surface of the respective lead.

17. The IC package of claim 15, wherein each test pad extends from a side of the respective lead, each test pad is an integral part of the respective lead, and each test pad protruding away from the bottom surface of the respective lead.

18. The IC package of claim 17, wherein each test pad is located adjacent to a corner of the respective lead, the plurality of leads each have a notch out of a corner or side, the notch configured to increase separation between test pads and neighboring leads, wherein each test pad is attached to a first corner of the respective lead and the notch corresponds to a missing second corner of the lead, the first corner and the notch positioned along a same side of the lead.

19. The IC package of claim 15, wherein each test pad is spaced apart from a side of the respective lead by a channel, the channel filled with the mold compound, and each test pad electrically coupled to the respective lead under the mold compound.

20. The IC package of claim 19, wherein each test pad is located adjacent to a corner of the respective lead, wherein each lead has a notch out of a corner or side, the notch configured to increase separation between the lead and neighboring test pad.
